(19) United States
(12) Patent Application Publication
(10) Pub. No.: US 2007/0093088 A1
(43) Pub. Date: Apr. 26, 2007

(54) ELECTROSTATIC DISCHARGE PROTECTION DEVICE

(75) Inventor: Mingsen Hsiao, Banciao City (TW)

Correspondence Address: ALSTON & BIRD LLP, BANK OF AMERICA PLAZA, 101 SOUTH TRYON STREET, SUITE 4000, CHARLOTTE, NC, 28280-4000, US

(73) Assignee: Inventec Appliances Corp.

(21) Appl. No.: 11/560,671

(22) Filed: Nov. 16, 2006

(30) Foreign Application Priority Data
Oct. 24, 2005 (TW) 94137187

(51) Int. Cl. H05K 1/00

(52) U.S. Cl. 439/76.1

(57) ABSTRACT

An electrostatic discharge protection device is provided. The electrostatic discharge protection device is disposed at a side of a printed circuit board of an electronic device, including a body portion, a first extending portion extended from the first flank, and a second extending portion extended from the second flank and being opposite to the first extending portion. The body portion includes a trough receiving the side of the printed circuit board, a first flank, and a second flank opposite to the first flank.

### FIELD OF THE INVENTION

The present invention relates to an electrostatic discharge protection device, and more particularly to an electrostatic discharge protection device disposed at a side of a printed circuit board and applied to an electronic device.

### BACKGROUND OF THE INVENTION

In a modern society, electronic devices can be seen everywhere in our life. Especially the portable electronic devices, which have features of lightweight, miniaturization and easy-taking, are very popular for modern people, wherein the portable electronic devices may be notebooks, personal digital assistants, or mobile phones.

However, the electronic devices are generally susceptible to an electrostatic discharge (ESD) event, which may damage or destroy the electronic devices. The transient voltage/current variation induced by an electrostatic discharge event is quite huge, but the toleration of integrated circuit components is only about 8000 Volts, and in fact, some high-speed components may be destroyed when electrostatic potential is over 30 Volts. The formation of the electrostatic discharge event is because the electric field formed by a charged object will induce the gas nearby to be ionized to discharge a large amount of current. When an electronic device with an upper and a lower covers is assembled, it is very easy to be invaded by charges associated with the ESD event through the interstice between the upper and the lower covers. The damage associated with the ESD event will decrease the life of the electronic device, so it is important to improve the techniques of electrostatic discharge protection.

Please refer to FIG. 1, which is a regional cross-section view of an electrostatic discharge protection device according to the prior art. The electronic device 11 includes an upper cover 111, a lower cover 112, and a printed circuit board 113, wherein the upper cover 111 has a first flank and the lower cover 112 has a second flank. When the upper cover 111 on the upside is assembled with the lower cover 112, the second flank will overlap the first flank, and an interstice 12 where the ESD event easily occurs will be created. The printed circuit board 113 is disposed between the upper and the lower covers 111, 112, and the overlapping area is extended to allow the charges associated with the ESD event to have enough space to be drained away without creating a damaging current density. However, this kind of protective device will increase the volume of the electronic device 11, which thus increases the difficulty for miniaturization.

Please refer to FIG. 2, which is a regional cross-section view of another electrostatic discharge protection device according to the prior art. The electronic device 21 includes an upper cover 211, a lower cover 212, a printed circuit board 213 and a copper foil 214. When the upper cover 211 on the upside is assembled with the lower cover 212, an interstice 22 where the ESD event easily occurs is formed. The printed circuit board 213 is disposed between the upper cover 211 and the lower cover 212. The copper foil 214 receives the printed circuit board 213 and is connected to the ground, which allows the charges associated with the ESD event to be drained away. However, the protection is incomplete because of the remnants of the charges.

In order to overcome the drawbacks in the prior art, an electrostatic discharge protection device is provided. The particular design in the present invention not only solves the problems described above, but also is easy to be implemented. Thus, the invention has the utility for the industry.

### SUMMARY OF THE INVENTION

In accordance with the present invention, there is provided an electrostatic discharge protection device for an electronic device, which is disposed at a side of a printed circuit board of an electronic device to allow the charges, associated with ESD events to be drained away. In addition, the electrostatic discharge protection device with extending portions can separate the printed circuit board from an upper and a lower covers of the electronic device, which reduces the numbers of protecting and supporting components and increases their lives.

In one aspect, the electrostatic discharge protection device comprises a body portion, a first extending portion, and a second extending portion. The body portion that is an elongate column includes a trough, a first flank, and a second flank opposite to the first flank, wherein the trough receives the side of the printed circuit board. The first extending portion extends from the first flank, and the second extending portion opposite to the first extending portion extends from the second flank.

Preferably, each of the first and the second extending portions is an arc.

Preferably, the electronic device further comprises an upper cover having a first inner side and a lower cover having a second inner side, wherein the lower cover is able to assemble to the upper cover. The first inner side of the upper cover and the first extending portion contact with each other, and similarly, the second inner side of the lower cover and the second extending portion contact with each other. [00111 Preferably, the electrostatic discharge protection device is made of a plastic or a rubber or any other insulator, which prevents the charges associated with the ESD event from being transmitted to the printed circuit board. Besides, the electrostatic discharge protection device can be applied to different kinds of electronic devices, and has the vibration-preventing function at the same time.

In accordance with another aspect of the invention, there is provided an electronic device with an electrostatic discharge protection device, which comprises a printed circuit board with a side and an electrostatic discharge protection device disposed at the side. In addition, the electrostatic discharge protection device further includes a body portion, a first extending portion, and a second extending portion. The body portion that is an elongate column includes a trough, a first flank, and a second flank opposite to the first flank, wherein the trough receives the side of the printed circuit board. The first extending portion extends from the first flank, and the second extending portion opposite to the first extending portion extends from the second flank.

Preferably, each of the first and the second extending portions is an arc.

Preferably, the electronic device further comprises an upper cover having a first inner side and a lower cover having a second inner side, wherein the lower cover is able to assemble to the upper cover. The first inner side of the upper cover and the first extending portion contact with each other, and similarly, the second inner side of the lower cover and the second extending portion contact with each other.

Preferably, the electrostatic discharge protection device is made of a plastic or a rubber or any other insulator, which prevents the charges associated with the ESD event from being transmitted to the printed circuit board.

In accordance with a further aspect of the present invention, an electrostatic discharge protection device is provided. The electrostatic discharge protection device is disposed at a side of a printed circuit board with a cover, and comprises a body having a trough receiving the side, and an extending portion extended from the body and connecting with the cover.

The above objects and advantages of the present invention will become more readily apparent to those ordinarily skilled in the art after reviewing the following detailed descriptions and accompanying drawings, in which:

### BRIEF DESCRIPTION OF THE DRAWINGS

FIG. 1 is a regional cross-section view of an electrostatic discharge protection device for an electronic device according to the prior art;

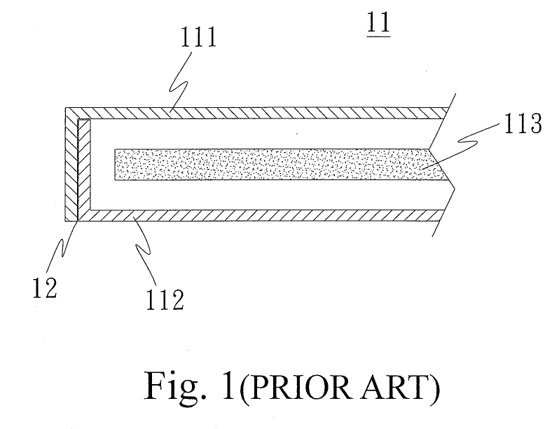

FIG. 2 is a regional cross-section view of another electrostatic discharge protection device for an electronic device according to the prior art;

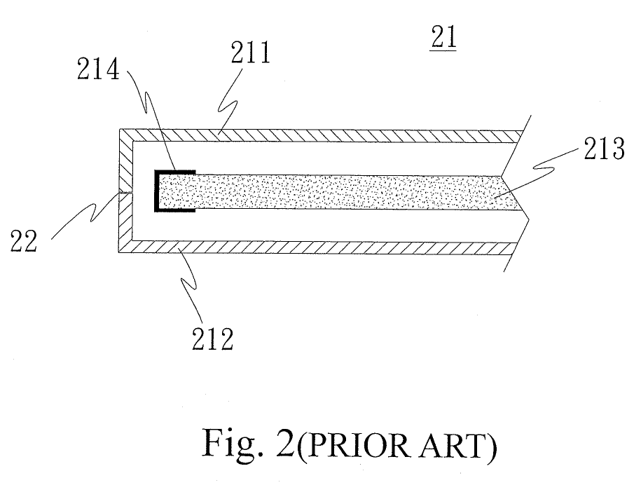

FIG. 3 is a cross-section view of an electrostatic discharge protection device according to a preferred embodiment of the present invention;

FIG. 4 is a diagram showing the assembly of the electrostatic discharge protection device and a printed circuit board according to a preferred embodiment of the present invention; and

FIG. 5 is a regional cross-section view of an electronic device comprising the electrostatic discharge protection device according to the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for the purposes of illustration and description only; it is not intended to be exhaustive or to be limited to the precise form disclosed.

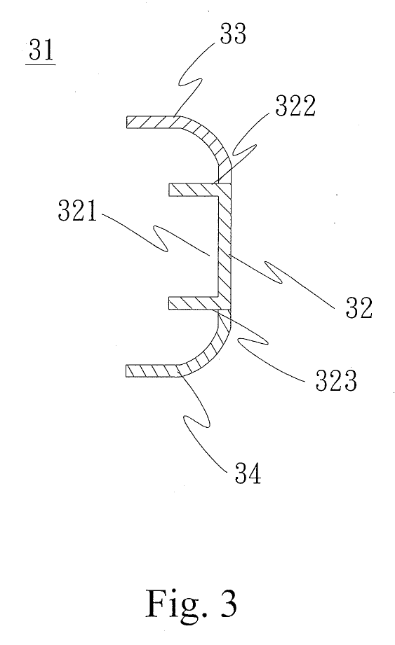

Please refer to FIG. 3, which is a cross-section view of an electrostatic discharge protection device according to a preferred embodiment of the present invention, wherein the electrostatic discharge protection device is disposed at a side of a printed circuit board, and can be applied to an electronic device. The electrostatic discharge protection device 31 comprises a body portion 32, a first extending portion 33, and a second extending portion 34. The body portion 32 that is an elongate column includes a trough 321, a first flank 322, and a second flank 323 opposite to the first flank 322. The first extending portion 33 extends from the first flank 322, and the second extending portion 34 opposite to the first extending portion 33 extends from the second flank 323, wherein each of the first and the second extending portions is an arc. In addition, the electrostatic discharge protection device is made of a plastic or a rubber, and the electronic device can be a portable electronic device such as a notebook, a personal digital assistant, or a mobile phone. The electrostatic discharge protection device according to the invention can be integrally made by one-shot plastic injection molding.

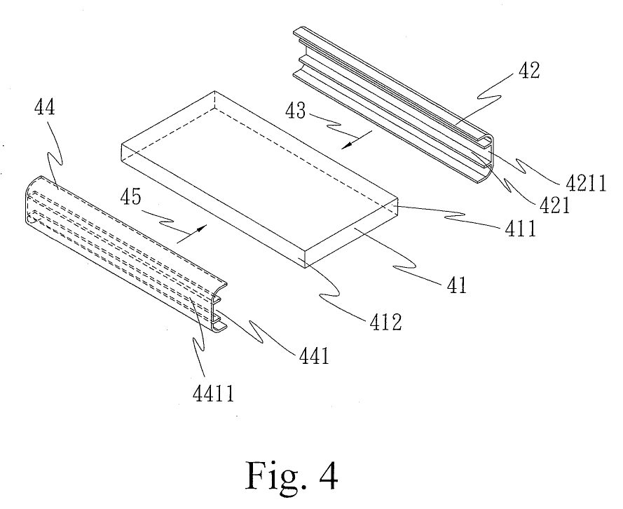

Please refer to FIG. 4, which is a diagram showing the assembly of the electrostatic discharge protection device and a printed circuit board according to a preferred embodiment of the present invention. The printed circuit board 41, such as a mainboard, has a first flank 411 and a second flank 412 opposite to the first flank 411. Firstly, the first trough 421 of the first electrostatic discharge protection device 42 is assembled with the printed circuit board 41 in the direction 43, by engaging the first inner side 4211 of the first trough 421 with the first flank 411. Next, the second trough 441 of the second electrostatic discharge protection device 44 is assembled with the printed circuit board 41 in the direction 45, by engaging the second inner side 4411 of the second trough 441 with the second flank 412. Besides, the size of the electrostatic discharge protection device according to the present invention can be varied to match that of the printed circuit board, and most electrostatic discharge events can be prevented by only two electrostatic discharge protection devices.

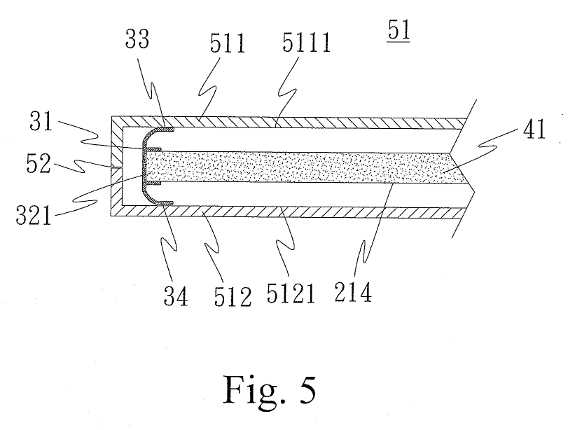

Please refer to FIG. 5, which is a regional cross-section view of an electronic device comprising the electrostatic discharge protection device according to the present invention. The electronic device 51 includes an upper cover 511 having a first inner side 5111, a lower cover 512 having a second inner side 5121 and being able to assemble to the upper cover, a printed circuit board 41, and at least one electrostatic discharge protection device 31 having a first and a second extending portions 33 and 34. The first inner side 5111 of the upper cover 511 contacts with the first extending portion 33 of the electrostatic discharge protection device 31, and the second inner side 5121 of the lower cover 512 contacts with the second extending portion 34 of the electrostatic discharge protection device 31. The trough 321 of the electrostatic discharge protection device 31 receives the side of the printed circuit board 41. After the assembly, the space among the upper cover 511, the lower cover 512, and the electrostatic discharge protection device 31 can provide enough space to allow the charges associated with the ESD event to be drained away, and the electronic device 51 still can be miniaturized.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. An electrostatic discharge protection device disposed at a side of a printed circuit board of an electronic device, comprising:
a body portion, comprising:
a trough receiving the side of the printed circuit board;
a first flank; and
a second flank opposite to the first flank;
a first extending portion extended from the first flank; and
a second extending portion extended from the second flank and being opposite to the first extending portion.

2. The electrostatic discharge protection device as claimed in claim 1, wherein each of the first and the second extending portions is an arc.

3. The electrostatic discharge protection device as claimed in claim 1, wherein the electrostatic discharge protection device is made of a plastic.

4. The electrostatic discharge protection device as claimed in claim 1, wherein the electrostatic discharge protection device is made of a rubber.

5. The electrostatic discharge protection device as claimed in claim 1, wherein the electronic device further comprises an upper cover having a first inner side and a lower cover having a second inner side, wherein the lower cover is able to be assembled to the upper cover.

6. The electrostatic discharge protection device as claimed in claim 5, wherein the first inner side of the upper cover and the first extending portion contact with each other.

7. The electrostatic discharge protection device as claimed in claim 5, wherein the second inner side of the lower cover and the second extending portion contact with each other.

8. The electrostatic discharge protection device as claimed in claim 1, wherein the printed circuit board is a mainboard.

9. The electrostatic discharge protection device as claimed in claim 1, wherein the body portion is an elongate column.

10. The electrostatic discharge protection device as claimed in claim 1, wherein the electronic device is a portable electronic device.

11. The electrostatic discharge protection device as claimed in claim 10, wherein the portable electronic device is a notebook.

12. The electrostatic discharge protection device as claimed in claim 10, wherein the portable electronic device is a personal digital assistant.

13. The electrostatic discharge protection device as claimed in claim 10, wherein the portable electronic device is a mobile phone.

14. An electronic device, comprising:
a printed circuit board with a side; and
an electrostatic discharge protection device disposed at the side of the printed circuit board, comprising:
a body portion, comprising:
a trough receiving the side of the printed circuit board;
a first flank; and
a second flank opposite to the first flank;
a first extending portion extended from the first flank; and
a second extending portion extended from the second flank and being opposite to the first extending portion.

15. The electronic device as claimed in claim 14, wherein each of the first and the second extending portions is an arc.

16. The electronic device as claimed in claim 14, wherein the electrostatic discharge protection device is made of one of a plastic and a rubber.

17. The electronic device as claimed in claim 14, wherein the electronic device further comprises an upper cover having a first inner side and a lower cover having a second inner side, wherein the lower cover is able to be assembled to the upper cover.

18. The electronic device as claimed in claim 17, wherein the first inner side of the upper cover and the first extending portion contact with each other.

19. The electronic device as claimed in claim 17, wherein the second inner side of the lower cover and the second extending portion contact with each other.

20. An electrostatic discharge protection device disposed at a side of a printed board with a cover, comprising:
a body having a trough receiving the side; and
an extending portion extended from the body and connecting with the cover.
